(19) United States
(12) Patent Application Publication
(10) Pub. No.: US 2025/0062142 A1
(43) Pub. Date: Feb. 20, 2025

(54) SUBSTRATE HEAT TREATMENT APPARATUS COTROLLING INDIVIDUALLY THE OUTPUT OF THE VCSEL MODULE

(71) Applicant: Viatron Co., Ltd., Gyeonggi-do (KR)

(72) Inventors: Hyoung June Kim, Seoul (KR); Byung Kuk Kim, Gyeonggi-do (KR); Wang Jun Park, Gyeonggi-do (KR); Tae Hyeong Kim, Gyeonggi-do (KR)

(21) Appl. No.: 18/721,571

(22) PCT Filed: Dec. 28, 2022
(86) PCT No.: PCT/KR2022/021502

§ 371 Date: Jun. 18, 2024

(30) Foreign Application Priority Data
Dec. 30, 2021 (KR) 10-2021-0192703

(51) Int. Cl. H01L 21/67; F27B 17/00; H01L 21/687

(52) U.S. Cl. CPC H01L 21/67115; F27B 17/0025; H01L 21/68764

(57) ABSTRACT

This present disclosure discloses a substrate heat-treating apparatus including a process chamber in which a flat substrate to be heat-treated is placed and a beam irradiating module having a plurality of VCSEL devices configured to irradiate a laser beam to the flat substrate, and the beam irradiation module is configured such that a supply current is controlled to allow outputs of the VCSEL devices to become the same.

### TECHNICAL FIELD

The present disclosure relates to a substrate heat-treating apparatus which heat-treats a flat substrate using a laser beam irradiated from a VCSEL device.

### BACKGROUND ART

A semiconductor wafer or a flat substrate such as a glass substrate for a flat panel display device may be manufactured into a semiconductor or flat panel display module by performing a heat treatment process such as an epitaxial process, a thin film crystallization process, an ion implantation process, or an activation process.

The epitaxial process is a process for growing a required thin film on a surface of the semiconductor wafer. The epitaxial process is performed by injecting a process gas into a process chamber maintained at a high temperature of 600° C. or higher in a vacuum state. It is necessary to uniformly maintain a temperature of the semiconductor wafer throughout the process, and it is necessary to reduce the influence caused by emissivity of an external housing constituting the process chamber. In particular, the emissivity of a component or a wall, which is one of the components of the external housing and faces an upper surface of the semiconductor wafer, affects a process temperature of the semiconductor wafer, so it is necessary to maintain constant emissivity.

Meanwhile, in recent, a heat treatment process for heating the semiconductor wafer using a vertical cavity surface emitting laser (VCSEL) device has been developed. The above-mentioned heat treatment process is a method for heat-treating the semiconductor wafer by uniformly irradiating a laser beam on the semiconductor wafer using a beam irradiating module in which a plurality of VCSEL devices are disposed to cover a large surface region and irradiate a laser beam. In the VCSEL device, a micro-emitter may emit a laser beam. The beam irradiating module utilizes divergence of a laser beam emitted from the VCSEL device, and may uniformly heat the semiconductor wafer through overlapping of laser beams emitted from the VCSEL devices adjacent to each other. The beam-irradiating module consists of the plurality of VCSEL devices, and the plurality of VCSEL devices may be disposed in up to a region covering the entire semiconductor wafer.

In recent, the above-mentioned heat treatment process requires a small temperature deviation and high temperature uniformity in response to miniaturization of semiconductor technology. However, the currently employed heat treatment apparatus has a problem in that it is difficult to realize the required temperature uniformity due to various limitations.

### DISCLOSURE OF THE INVENTION

### Technical Problem

An object of the present disclosure is to provide a substrate heat-treating apparatus capable of controlling an individual output of a VCSEL device, capable of reducing a temperature deviation of a flat substrate and increasing temperature uniformity during a heat treatment process for the flat substrate.

An object of the present disclosure is to provide a substrate heat-treating apparatus which can individually control a supply current supplied to the VCSEL devices so that outputs of the VCSEL devices become uniform.

### Technical Solution

A substrate heat-treating apparatus, which can control an individual output of a VCSEL device, includes a process chamber in which a flat substrate to be heat-treated is placed; and a beam irradiating module comprising a plurality of VCSEL devices, and configured to irradiate a laser beam to the flat substrate, wherein the beam irradiating module is configured such that a supply current is controlled to allow outputs of the VCSEL devices to become the same.

Also, VCSEL devices may be supplied with supply currents which differ from each other, respectively.

The beam irradiating module may be configured such that the VCSEL devices are supplied with supply currents which differ from each other, respectively.

In addition, a correlation between a supply current and an output may be set in advance for each VCSEL device.

Furthermore, the correlation of the VCSEL device is set as an equation or a lookup table.

In addition, each of the VCSEL devices is supplied with a supply current for the required output depending on the correlation.

### Advantageous Effects

The substrate heat-treating apparatus, which can control an individual output of a VCSEL device, according to the present disclosure individually controls supply power supplied to a plurality of VCSEL devices, so that it is possible to make outputs of the VCSEL devices uniform in their entirety.

In addition, the substrate heat-treating apparatus, which can control an individual output of a VCSEL device, according to the present disclosure supplies supply currents individually differently depending on a relation between a supply current evaluated in advance and an output for each VCSEL device, thereby controlling outputs uniformly in their entirety and reducing a temperature deviation of the flat substrate.

### BRIEF DESCRIPTION OF THE DRAWINGS

FIG. 1 is a view illustrating a configuration of a substrate heat-treating apparatus according to one embodiment of the present disclosure;

FIG. 2 is a plan view of a beam irradiating module of FIG. 1;

FIG. 3 is a partial perspective view of the beam irradiating module of FIG. 2;

FIG. 4 is a vertical cross-sectional view a VCSEL device, taken along line “A-A” of FIG. 3;

FIG. 5 is a plan view showing a position at which a temperature of a semiconductor wafer is measured in the substrate heat-treating apparatus of FIG. 1;

FIG. 6 is a table for measurement data of a supply current and a measured optical output for each time interval of the VCSEL devices constituting the beam irradiating module of FIG. 5;

FIG. 7 shows a graph and three-dimensional equation for a correlation of the No. 7 VCSEL device;

FIG. 8 shows a graph and three-dimensional equation for a correlation of the No. 8 VCSEL device;

FIG. 9 shows a graph and a three-dimensional equation for a correlation of the No. 8 VCSEL device;

FIG. 10 is a graph showing the results of measuring a temperature distribution on the semiconductor wafer of FIG. 5; and

FIG. 11 is a graph showing the results of measuring a temperature distribution on the semiconductor wafer in a conventional substrate heat-treating apparatus.

### BEST MODE FOR CARRYING OUT THE INVENTION

Hereinafter, a substrate heat-treating apparatus, which is capable of controlling individual output of a VCSEL device, of the present disclosure is described in detail with reference to embodiments and the accompanying drawings.

First, a configuration of a substrate heat-treating apparatus capable of individual output control of a VCSEL device according to one embodiment of the present disclosure will be described.

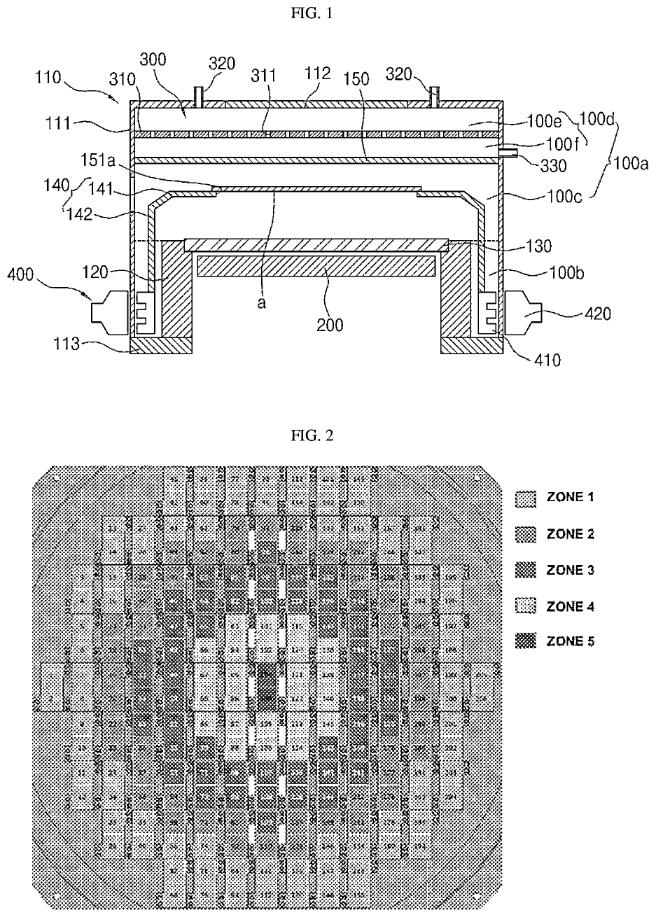

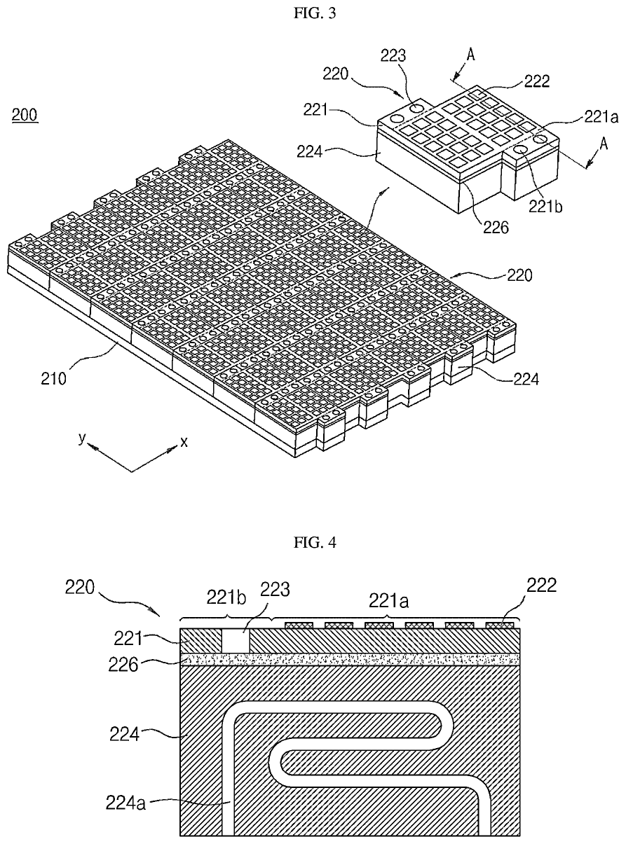

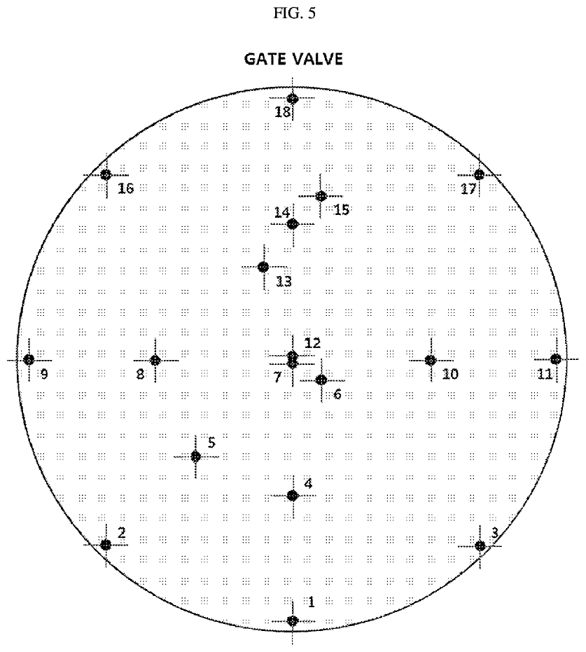

FIG. 1 is a view illustrating a configuration of a substrate heat-treating apparatus according to one embodiment of the present disclosure, FIG. 2 is a plan view of a beam irradiating module of FIG. 1, FIG. 3 is a partial perspective view of the beam irradiating module of FIG. 2, and FIG. 4 is a vertical cross-sectional view taken along line “A-A” of a VCSEL device of FIG. 3.

Referring to FIGS. 1 to 4, a substrate heat-treating apparatus 10 capable of controlling individual output of a VCSEL device according to one embodiment of the present disclosure includes a process chamber 100, a beam irradiating module 200, a gas spraying module 300 and a substrate rotating module 400.

In the substrate heat-treating apparatus 10, a manufacturing process such as an epitaxial process, a crystallization process, an ion implantation process, or an activation process for a flat substrate a may be performed. Here, the flat substrate a may be a semiconductor wafer or a glass substrate. In addition, the flat substrate a may be a flexible substrate such as a resin film. Furthermore, the flat substrate a may include various elements or electrically conductive patterns formed therein or on a surface thereof.

The substrate heat-treating apparatus 10 may use the VCSEL device as a heat light source in the beam irradiating module for heating the flat substrate a. In addition, the VCSEL device may irradiate a laser beam with a single wavelength. For example, the VCSEL device may preferably be a device that may irradiate a laser beam with a single wavelength of approximately 940 nm. The substrate heat-treating apparatus 10 may irradiate a laser beam generated from the beam irradiating module 200 to the flat substrate a to heat the flat substrate a.

The substrate heat-treating apparatus 10 supplies a current depending on a pre-evaluated relation between a supply current and an output for each VCSEL device constituting the beam irradiating module 200, so that it is possible to make output of the VCSEL devices uniform. Therefore, the substrate heat-treating apparatus may uniformly heat the flat substrate in its entirety.

The process chamber 100 may include an external housing 110, an internal housing 120, a beam irradiating plate 130, a substrate support 140, and an infrared-ray transmitting plate 150. The process chamber 100 may provide a space in which a flat substrate a is received and heat-treated. The flat substrate a may be supported by the substrate support 140 inside the process chamber 100. The process chamber 100 allows a laser beam generated from the beam irradiating module 200 placed outside the process chamber to be irradiated to a lower surface of the flat substrate placed inside the process chamber. The process chamber 100 allows a laser beam to pass through the beam irradiating plate 130 and be irradiated to the lower surface of the flat substrate a seated on the substrate support 140.

The external housing 110 is formed in a hollow pillar shape, and may include a side wall 111, an upper plate 112, and a lower plate 113. The external housing 110 may be formed in a substantially cylindrical shape, a rectangular column shape, a pentagonal column shape, or a hexagonal column shape. The external housing 110 may be formed into a shape having a horizontal cross-sectional area larger than an area of the flat substrate a to be heat-treated therein.

The side wall 111 may be formed in a hollow cylindrical shape, a hollow square column shape, a hollow pentagonal column shape, or a hollow hexagonal column shape. The side wall 111 provides a chamber upper space 100a within which a heat treatment is performed. In addition, the side wall 111 provides a space in which parts of the beam irradiating module 200 and the substrate rotating module 400 are received.

The upper plate 112 may be formed in a plate shape corresponding to a top planar shape of the side wall 111. The upper plate 112 is coupled to an upper end of the side wall 111 and may seal hermetically an upper portion of the side wall 111.

The lower plate 113 corresponds to a lower planar shape of the side wall 111, and has a lower through hole 113 formed in an inside portion thereof. The lower plate 113 may be formed in a circular ring or square ring with a predetermined width. The lower plate 113 may be formed in various shapes depending on a lower planar shape of a chamber lower space 100b. The lower plate 113 is coupled to a lower portion of the side wall 111 and seals hermetically an outer side of the side wall 111. A lower portion of the internal housing 120, which will be described below, may be coupled to an outer side of the through hole of the lower plate 113.

The internal housing 120 is formed in a hollow column shape, and may be formed in a cylindrical shape, a square column shape, a pentagonal column shape, or a hexagonal column shape. The internal housing 120 may be formed with an outer diameter or an outer width that is smaller than an inner diameter or an inner width of the external housing 110. Also, the internal housing 120 may be formed to have a height lower than that of the external housing 110. In addition, the internal housing 120 may be formed with a height such that its upper side is positioned below the flat substrate a seated placed inside the process chamber 100. Furthermore, the internal housing 120 may be formed to have a diameter or width larger than a diameter or width of the flat substrate a placed thereabove. Alternatively, the internal housing 120 may be formed to have a horizontal area greater than that of the flat substrate a. Thus, an upper chamber space 100a in which the flat substrate a is placed is formed at the upper portion of the internal housing 120. That is, the chamber upper space 100a is formed inside the external housing 110 and above the internal housing 120, and provides a space in which the flat substrate a is placed. The flat substrate a may be placed in the chamber upper space 100a such that a lower surface of a region thereof to be heat-treated is exposed when viewed from a lower portion of the internal housing 120.

In addition, the internal housing 120 may be coupled such that its lower side and a lower side of the external housing 110 are at approximately the same height. A lower end of the internal housing 120 may be coupled to an inner side of the lower plate 113. Accordingly, a space between an outer side of the internal housing 120 and an inner side of the external 110 may be hermetically sealed by the lower plate 113. The chamber lower space 100b may be formed between an outer surface of the internal housing 120 and an inner surface of the external housing 110. The chamber upper space 100a and the chamber lower space 100b may be maintained in a vacuum or process gas atmosphere while being shielded from the outside by the external housing 110, the internal housing 120, and the lower plate 113.

The beam irradiating plate 130 is coupled to the upper portion of the internal housing 120 and may be placed below the flat substrate a. The beam irradiating plate 130 may be formed of a transparent plate through which a laser beam passes, such as quartz or glass. The beam irradiating plate 130 allows a laser beam to pass therethrough and be irradiated to the lower surface of the flat substrate a. More specifically, the beam irradiating plate 130 allows a laser beam incident from the inside of the internal housing 120 through a lower surface thereof to be irradiated to the lower surface of the flat substrate a. The beam irradiating plate 130 may be formed to have an area larger than that of the flat substrate a. For example, the beam irradiating plate 130 may be formed to have a diameter or a width greater than a diameter or a width of the flat substrate a. The beam irradiating plate 130 may preferably be formed to have a diameter or width of 1.1 times or more than a diameter or a width of the flat substrate a. In this case, the beam irradiating plate 130 may allow a laser beam to be irradiated to the lower surface of the flat substrate a in its entirety.

The substrate support 140 may include an upper support 141 and a connecting support 142. The substrate support 140 is placed at the upper portion of the internal housing 120, and may support a peripheral portion of the lower surface of the flat substrate a so that the lower surface of the flat substrate a is exposed. In addition, the substrate support 140 may extend into the chamber lower space 100b to be coupled to the substrate rotation module 400. Due to action of the substrate rotating module 400, the substrate support 140 may rotate the flat substrate a.

The upper support 141 is provided with a substrate exposing hole 141a formed in an inside portion thereof, and may be formed in a ring shape with a predetermined width. The upper support 141 may support a peripheral portion of the lower surface of the flat substrate a while exposing the lower surface of the flat substrate a. The upper support 141 may be formed to have a diameter or a width greater than a diameter or a width of the flat substrate a.

The substrate exposing hole 141a may be formed in a central portion of the upper support 141, and extends from an upper surface to a lower surface of the upper support. The substrate exposing hole 141a may be formed to have a predetermined area such that it enables a region of the lower surface of the flat substrate a, which requires a heat treatment, to be exposed in its entirety.

The connecting support 142 is roughly formed in a pillar shape with opened upper and lower ends, and may be formed in a shape corresponding to the shape of the internal housing 120. For example, when the internal housing 120 is formed in a cylindrical shape, the lower support may be formed in a cylindrical shape corresponding to this shape of the internal housing. The connecting support 142 may be positioned across the upper chamber space 100a and the lower chamber space 100b. An upper portion of the connecting support 142 is coupled to an outer side of the upper support 141, and a lower portion may extend into the chamber lower space 100b to be coupled to the substrate rotating module 400. Therefore, the connecting support 142 may be rotated by the substrate rotating module 400 to rotate the upper support 141 and the flat substrate a.

The infrared-ray transmitting plate 150 may be formed in a plate shape corresponding to a planar shape of the upper portion of the side wall 111. The infrared-ray transmitting plate 150 may be formed from transparent quartz. The infrared-ray transmitting plate 150 may be placed between the upper plate 112 and the substrate support 140 at the upper portion of the side wall 111. The infrared-ray transmitting plate 150 may divide the chamber upper space 100a of the external housing 110 into a heat treatment space 100c and a cooling gas space 100d. The heat treatment space is a space where the flat substrate a is placed and heat treatment is performed. The cooling gas space is a space into which cooling gas used for cooling the infrared-ray transmitting plate 150 flows, and is positioned at an upper portion of the heat treatment space. Above the flat substrate a, the infrared-ray transmitting plate 150 may be positioned to allow its lower surface to face an upper surface of the flat substrate a. Meanwhile, the infrared-ray transmitting plate 150 may form an upper surface of the external housing 110, and the side wall 111 and the upper plate 112 of the upper part of the infrared transmitting plate 150 may be separately formed to be coupled to the upper portion of the infrared transmitting plate 150.

The infrared-ray transmitting plate 150 may be formed from transparent quartz to transmit radiant energy generated from the flat substrate a during a heat treatment process to the outside. In particular, the infrared-ray transmitting plate 150 may transmit radiant energy, which has a wavelength including a wavelength of an infrared ray, to the outside. In addition, the infrared-ray transmitting plate 150 may be maintained at a temperature of 400° C. or less, and preferably at a temperature of 300 to 400° C. Since the infrared-ray transmitting plate 150 is maintained at a temperature of 300 to 400° C., a chemical deposition caused by a process gas can be prevented to prevent an increase in emissivity due to the deposition. Here, the process gas may vary depending on the type of heat treatment process. For example, in an epitaxial process, gases such as SiH4, SiH2Cl2, SiHCl3, or SiCl4 may be used as the process gas.

The chemical deposition may be significantly reduced when the temperature of the cooling gas is 400° C. or less. In addition, since the emissivity of the infrared-ray transmitting plate 150 is not increased depending on the number of heat treatment processes, it is possible to reduce difference in a process temperature between the flat substrates a on which the process is being performed.

The beam irradiating module 200 may include a device array plate 210 and a

VCSEL device 220. The beam irradiating module 200 may be positioned at an outer lower portion of the process chamber 100 to irradiate a laser beam to the lower surface of the flat substrate a through the beam irradiating plate 130. The beam irradiating module 200 may be placed below the beam irradiating plate 130 within the internal housing 120. The beam irradiating module 200 may be placed below the beam irradiating plate 130 within the internal housing 120.

In the beam irradiating module 200, the plurality of VCSEL devices 220 may be arranged in a lattice form on an upper surface of the device array plate 210. Referring to FIGS. 2 and 3, the VCSEL devices 220 may be arranged on the upper surface of the device array plate 210 in a x-direction and a y-direction to be arranged in a lattice shape.

The device array plate 210 may be formed in a plate shape having a predetermined area and thickness. The device array plate 210 may be preferably formed to correspond to the shape and area of the flat substrate a. The device array plate 210 may be formed of thermally conductive ceramic material or metallic material. The device array plate 210 may function to dissipate heat generated from the VCSEL devices 220.

The VCSEL device 220 may include a device substrate 221, laser emitting units 222, an electrode terminal 223, and a cooling block 224. The plurality of VCSEL devices 220 may be arranged and positioned on the device array plate 210 in a lattice direction. The VCSEL devices 220 may be arranged on a region of a surface of the device array plate 210 which is required for irradiating a laser beam to an irradiation region of the flat substrate a. The device substrate 221 may be coupled to the cooling block 224 by a separate adhesive layer 226.

The plurality of VCSEL devices may be supplied with supply current so that a plurality of optical outputs are uniform. That is, a supply current supplied to each of the VCSEL devices may be individually controlled so that the optical outputs can be uniform in their entirety. Here, the optical output may mean the radiant energy or output of a laser beam irradiated by the VCSEL device. The optical output may be measured using a measuring means such as a pyrometer. In addition, the VCSEL devices may be individually supplied with different supply currents depending on a pre-evaluated relation between a supply current and an optical output. Accordingly, the VCSEL devices may uniformly control an optical output in their entirely, and reduce a temperature deviation of the flat substrate.

With respect to a plane of the semiconductor wafer, a central portion and a peripheral of the VCSEL device may be independently supplied with different supply currents. In addition, as shown in FIG. 2, the VCSEL devices are divided into a plurality of zones, and a supply current may be supplied independently and differently for each zone. However, even in this case, the VCSEL devices may be supplied with different supply currents. Since the laser emitting unit constituting the VCSEL device has a unique optical efficiency, even if the same current is supplied to the VCSEL devices, the optical outputs the VCSEL devices may not be the same. Therefore, an output depending on a supply current for each of the VCSEL devices may be measured in advance, and a supply current for the required output may be individually determined and supplied.

The VCSEL device 220 is formed by arranging a plurality of laser emitting units 222 in a x-axial direction and a y-axial direction. Although not specifically illustrated, the VCSEL device 220 may include a light emitting frame (not shown) for securing the laser emitting units 222, and a power line (not shown) for supplying a current to the laser emitting units 222. The VCSEL device 220 may be formed such that the same current is applied to the entire laser emitting units 222. In addition, the VCSEL device 220 may be formed such that different electric powers are applied to each of the laser emitting units 222.

The device substrate 221 may be formed of a general substrate used to mount electronic devices. The device substrate 221 may be divided into a device region 221a on which the laser emitting unit 222 is mounted, and a terminal region 221b on which a terminal is mounted. On the device region area 221a, the plurality of laser emitting units 222 arranged and mounted in a lattice shape. The terminal region 221b is placed to be adjacent to the device region 221a, and a plurality of terminals may be mounted on this region.

The laser emitting unit 222 may be formed of various light emitting devices that emit a laser beam. Preferably, the laser emitting unit 222 may be formed of a VCSEL (Vertical Cavity Surface Emitting Laser) unit. The VCSEL unit may irradiate a laser beam with a single wavelength of 940 nm. The VCSEL unit is formed in a quadrangle shape, and may preferably be formed in a square shape or a rectangular shape with a width-to-length ratio not exceeding 1:2. The VCSEL unit is manufactured as a hexahedral shaped chip, and a high-powered laser beam is oscillated from one side of this unit. Since the VCSEL unit oscillates a high-powered laser beam, as compared to existing halogen lamps, this VCSEL unit can increase the rate of increase in temperature of the flat substrate a and its life span is relatively long.

In the device region 221a, the plurality of the laser emitting units 222 may be arranged on an upper surface of the device substrate 221 in a x-direction and a y-direction to be arranged in a lattice shape. An appropriate number of the laser emitting units 222 may be arranged at appropriate intervals depending on the area of the device region 221a and the amount of energy of a laser beam irradiated to the flat substrate a. In addition, the laser emitting units 222 may be positioned at an interval such that uniform energy may be irradiated when a laser beam emitted from one laser emitting unit overlaps a laser beam of the adjacent laser emitting unit 222. At this time, the laser emitting units 222 may be placed such that sides of one laser emitting unit and the adjacent laser emitting unit 222 are in contact with each other, so there is no separation distance therebetween.

The plurality of electrode terminals 223 may be formed on the terminal region 221b of the device substrate 221. The electrode terminal 223 includes a positive (+) terminal and a negative (−) terminal, and may be electrically connected to the laser emitting unit 222. Although not specifically illustrated, the electrode terminal 223 may be electrically connected to the laser emitting unit 222 in various ways. The electrode terminal 223 may supply a current required for driving the laser emitting units 222.

The cooling block 224 may be formed to have a planar shape corresponding to a planar shape of the device substrate 221, and a predetermined height. The cooling block 224 may be formed of a thermally conductive ceramic material or metallic material. The cooling block 224 may be coupled to the lower surface of the device substrate 221 by a separate adhesive layer. The cooling block 224 may dissipate downward heat generated from the laser emitting unit 222 mounted on the surface of the device substrate 221. The cooling block 224 may radiate heat generated from the laser emitting unit 222 mounted on the surface of the device substrate 221 downward. Therefore, the cooling block 224 may cool the device substrate 221 and the laser emitting unit 222.

A cooling passage 224a through which cooling water flows may be formed in the cooling block 224. The cooling passage 224a may have an inlet port and an outlet port formed in a lower surface of the cooling block, and may be formed in the cooling block 224 as various types of flow passages.

The gas spraying module 300 may include a gas spraying plate 310, a gas supply pipe 320, and a gas discharging pipe 330. The gas spraying module 300 may spray cooling gas to an upper surface of the infrared-ray transmitting plate 150 to cool the infrared-ray transmitting plate 150. The cooling gas may be nitrogen gas, argon gas, or compressed cooling air.

The gas spraying plate 310 is formed in a plate shape, and may have a gas spraying hole 311 which penetrates from an upper surface to a lower surface thereof. The gas spraying plate 310 may be placed parallel to the infrared-ray transmitting plate 150 between the upper plate 112 and the infrared-ray transmitting plate 150 at an upper portion of the external housing 110. The gas spraying plate 310 may separate a gas spraying space into an upper gas space and a lower gas space.

The gas spraying hole 311 is formed by penetrating from the upper surface to the lower surface of the gas injection plate 310. That is, the gas spraying hole 311 may communicate the upper gas space and the lower gas space. The gas spraying hole 311 may spray the cooling gas, which flows into the gas spraying space from the outside to the lower gas space.

The plurality of the gas spraying holes 311 may be formed in the gas spraying plate 310 to be entirely spaced apart from each other. The gas spraying holes 311 may more uniformly spray the cooling gas supplied into the upper gas space into the lower gas space. Therefore, the gas spraying plate 310 may more uniformly cool the infrared-ray transmitting plate 150 placed therebelow.

The gas supply pipe 320 is formed in a tubular shape with both opened sides, and is coupled to the upper plate 112 of the exterior housing 110 to communicate with the inside of the exterior housing 110. That is, the gas supply pipe 320 passes through the upper plate 112 from the outside to enter the upper gas space. The plurality of gas supply pipes 320 may be formed depending on the area of the upper plate 112. The gas supply pipe 320 may be connected to an external cooling gas supply apparatus to be supplied with the cooling gas.

The gas discharging pipe 330 is formed in a tubular shape with both opened sides, and may be coupled to the sidewall 111 of the external housing 110 to allow the lower gas space to communicate with the outside. That is, the gas discharging pipe 330 passes through the side wall 111 from the outside to enter the lower gas space. The plurality of gas discharging pipes 330 may be formed depending on the area of the upper plate 112. The gas discharging pipe 330 may discharge the cooling gas flowing into the lower gas space to the outside.

The substrate rotating module 400 may include an inner rotating means 410 and an outer rotating means 420. The substrate rotating module 400 may rotate the substrate support 140 in a horizontal direction in a non-contact manner. More specifically, the inner rotating means 410 may be coupled to a lower portion of the substrate support 140 in the chamber lower space 100b of the process chamber 100. In addition, the outer rotating means 420 may be positioned to face the inner rotating means 410 at the outside of the process chamber 100. The outer rotating means 420 may rotate the inner rotating means 410 in a non-contact manner using a magnetic force.

The inner rotating means 410 may be formed to have the same structure as a rotor of a motor. For example, the inner rotating means 410 may be formed as a magnet structure, which is formed in a ring shape in its entirely and has N poles and S poles alternately arranged in a circumferential direction. The inner rotating means 410 may be coupled to a lower portion of the substrate support 140, that is, the connecting support 142. At this time, the inner rotating means 410 may be placed to be spaced upward apart from an upper portion of the lower plate 113. Meanwhile, although not specifically depicted, the inner rotating means 410 may be supported by a separate support means to prevent vibration from being generated or to ensure that it can be rotated smoothly, during rotation thereof. For example, a lower portion of the inner rotating means 410 may be supported by a support bearing or a roller.

The outer rotating means 420 may be formed to have the same structure as a stator of a motor. For example, the outer rotating means 420 may include an iron core formed in a ring shape and an electrically conductive wire wound around the iron core. The outer rotating means 420 may rotate the inner rotating means 410 using a magnetic force generated by the electrical power supplied to the electrically conductive wire. The outer rotating means 420 may be placed outside the external housing 110 so as to face the inner rotating means 410 with respect to the external housing 110. In other words, the outer rotating means 420 may be placed outside the external housing with the respect to the external housing 110 at the same height as the inner rotating means 410.

Next, a method for controlling an output of the VCSEL device in the substrate heat-treating apparatus, which is capable of controlling an individual output control of the VCSEL device, according to one embodiment of the present disclosure will be described.

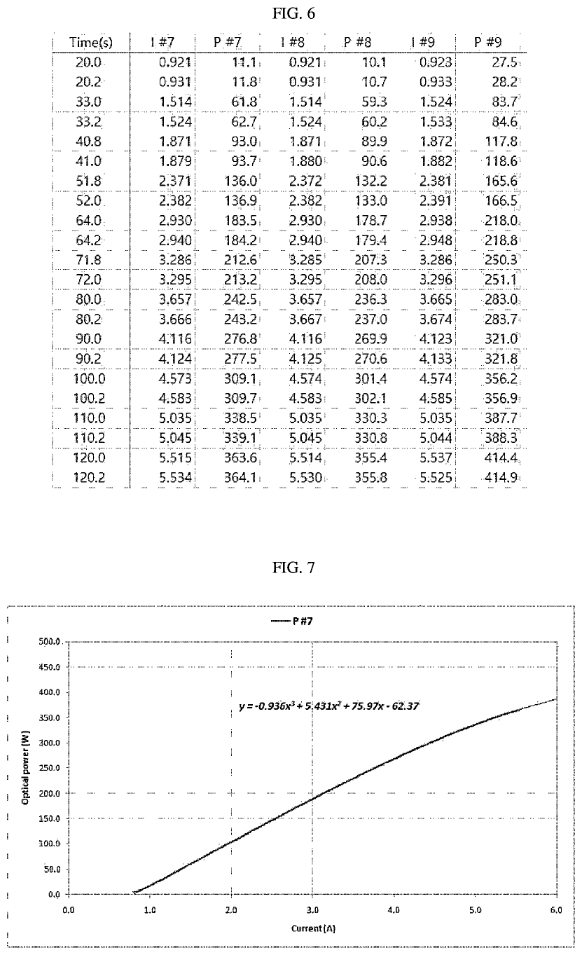

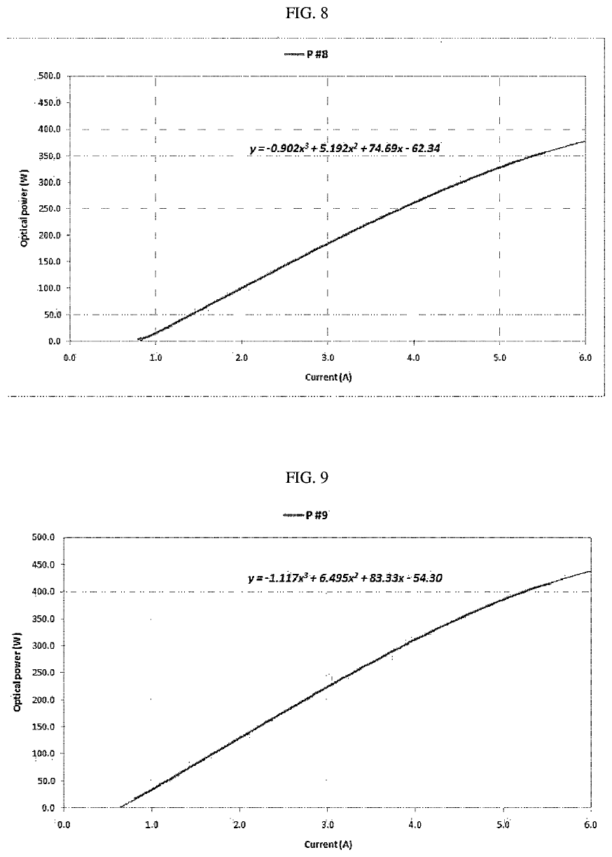

FIG. 5 is a plan view showing a position at which a temperature of the semiconductor wafer is measured in the substrate heat-treating apparatus of FIG. 1, FIG. 6 is a table for measurement data of a supply current and a measured optical output for each time interval of the VCSEL devices constituting the beam irradiating module of FIG. 5, FIG. 7 shows a graph and a three-dimensional equation for a correlation of the No. 7 VCSEL device, FIG. 8 shows a graph and three-dimensional equation for a correlation of the No. 8 VCSEL device, and FIG. 9 shows a graph and three-dimensional equation for a correlation of the No. 8 VCSEL device.

First, for the plurality of VCSEL devices used in the beam irradiating module 200, a supply current supplied to each VCSEL device and an output of a laser beam depending on a supply current are experimentally measured. In addition, a correlation between a supply current and an output for the VCSEL devices is set using the measurement results. In the VCSEL devices, even if the same current is supplied, outputs may be different depending on the characteristics of each laser emitting unit, an electrical resistance of the wire connecting the laser emitting units, and the like. That is, since the laser emitting units constituting each VCSEL device have a unique optical efficiency, the optical outputs output from the laser emitting units may not be the same even if the same current is supplied. Therefore, for the VCSEL device, an output depending on a supply current for each VCSEL device is measured in advance, and a supply current for the required output can be individually determined and supplied. In particular, the VCSEL devices may be supplied with different supply currents so that their outputs are the same in their entirety.

The correlation may be an equation or a lookup table for a supply current supplied to the VCSEL device and the optical output of a laser beam of the VCSEL device. The above correlation is set for all VCSEL devices used in the beam irradiating module 200, respectively. Accordingly, the correlation can be set in advance before the VCSEL devices is mounted on the beam irradiating module 200. When the VCSEL device is controlled by the correlation, as compared to the existing method of controlling only some section with relatively small calibration values, it is possible to increase temperature uniformity in terms of a degree of the temperature uniformity.

The correlation can be set as an equation after experimentally measuring a supply current supplied for each VCSEL device and an output depending thereon. The above output may be an optical output measured at a location spaced from the VCSEL device at a certain distance. Here, the separation distance may be a distance between the VCSEL device and the substrate in the substrate heat-treating device on which the VCSEL device is actually mounted. In addition, the above output may be an optical output measured by a pyrometer at a location spaced from the VCSEL device at a certain distance. Furthermore, the above output may be a temperature of the substrate to which a laser beam is irradiated. Here, the separation distance may be a distance between the VCSEL device and the substrate in the substrate heat treatment device in which the VCSEL device is actually mounted.

Hereinafter, a method for setting the correlation will be described in detail.

The correlation can be set as a three-dimensional equation. The correlation can be set as the optical output to a supply current.

For example, the measurement results for the VCSEL devices placed at positions indicated by numbers 7, 8, and 9 in FIG. 5 will be described. A supply current is increased from 0.000A to 5.530 at intervals of 0.005 to 0.010 A, and is supplied to the VCSEL device to be set. A supply current is increased at intervals of 0.2 seconds. The optical output is measured using a pyrometer placed at a set distance from the VCSEL device. FIG. 6 is a table for measurement data of a supply current and a measured optical output for each time interval. The data shown in FIG. 6 represents only a portion of the measurement data. As shown in FIG. 6, it can be confirmed that a supply current is increased at intervals of 0.02 seconds and the optical output is also increased. For the VCSEL device, a three-dimensional function is determined by fitting the data of the supplied supply current and the measured optical output. Graphs for a supply current and the optical output as shown in FIGS. 7, 8, and 9 are provided, and a three-dimensional equation for the graph is set. The graphs depicted in FIGS. 7, 8, and 9 are set to three-dimensional equations through a fitting process. It can be confirmed that numbers 7, 8, and 9 differ from each other in the coefficients of three-dimensional equations thereof. Therefore, it can be confirmed that, in each VCSEL device, there is a difference in the optical output even when the supplied current is the same. In the beam irradiating module, a three-dimensional equation for a supply current and an optical output is set for each VCSEL device.

Meanwhile, the table of a supply current and an optical output shown in FIG. 6 may be used as a lock-up table. That is, the table in FIG. 6 shows, for each VCSEL device, an optical outputs for a supply currents supplied at intervals of 0.005 to 0.01 A in the range from 0 A to 5.530 A, depending on the correlation between a supply current and an optical output. Therefore, the table of FIG. 6 may be employed as a lookup table that displays a supply current and an optical output corresponding thereto for each VCSEL device.

Furthermore, the correlation between a supply current and the optical output may be set as a two-dimensional equation or a four-dimensional or more equation in addition to a three-dimensional equation. In addition, although, in the above correlation, a supply current is set as an input (i.e., x value) and the optical output is set as an output (i.e., y value), conversely, the optical output may be set as an input (i.e., x value) and a supply current may be set as an output (i.e., y value).

Supply current required for the VCSEL devices of the beam irradiating module to output the same optical output is calculated by a cubic equation set for each VCSEL device. The VCSEL devices are controlled to be supplied with the calculated supply current and output a laser beam.

Next, the beam irradiating module 200 is mounted on the substrate heat-treating apparatus, and may irradiate a laser beam to heat the flat substrate. The VCSEL device may radiate a laser beam, which has an output required to heat the flat substrate to a set heating temperature, to the flat substrate. An output of the VCSEL device may be preset depending on the heating temperature of the flat substrate. In addition, an output of the VCSEL device may be changed by measuring the heating temperature of the flat substrate in real time during the heating process. Each of the VCSEL devices may be supplied with a supply current for required output. At this time, a supply current may be determined according to a preset correlation. The VCSEL devices may be supplied with different supply currents depending on the correlation which is set for each VCSEL device. Although not specifically depicted, the beam irradiating module 200 may be provided with a control module for controlling a supply current supplied to each of the VCSEL devices.

The following describes evaluation results for heating uniformity of the flat substrate obtained by the substrate heat-treating apparatus according to one embodiment of the present disclosure.

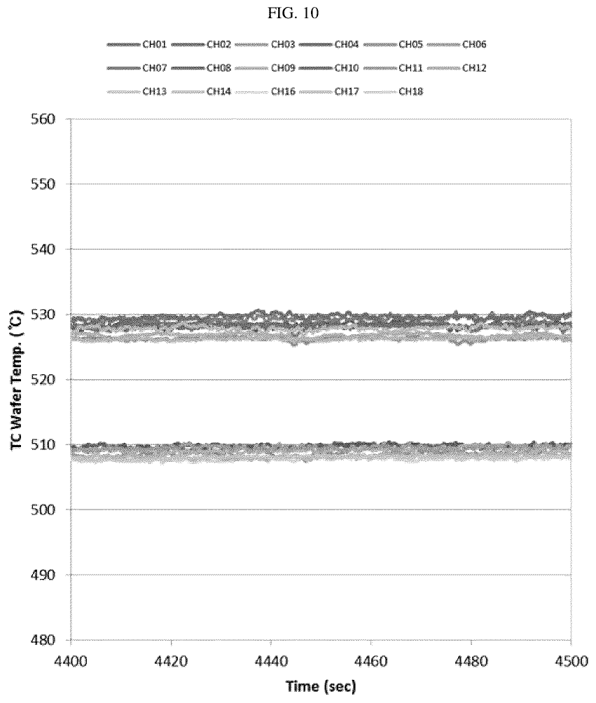

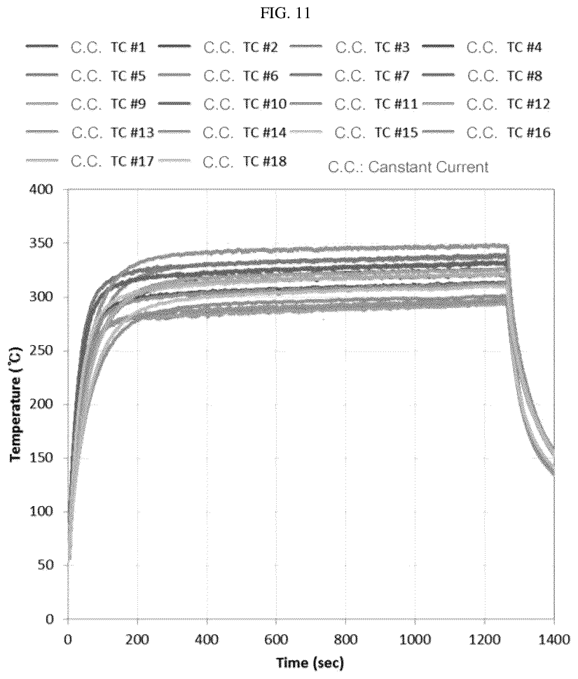

FIG. 10 is a graph showing the results of measuring a temperature distribution on the semiconductor wafer of FIG. 5. FIG. 11 is a graph showing the results of measuring a temperature distribution on the semiconductor wafer in a conventional substrate heat-treating apparatus.

The substrate heat-treating apparatus was set to heat a central portion of the semiconductor substrate to 528° C. and a peripheral portion to 509° C. The beam irradiating module 200 of the substrate heat-treating device set a supply current supplied to each VCSEL device as an output required for the set heating temperature. That is, the VCSEL devices were supplied with different supply currents, respectively, and irradiated a laser beam. A semiconductor wafer was used as the flat substrate. As depicted in FIG. 5, the substrate heat-heating apparatus measured the temperature of each of 18 locations of the semiconductor substrate. As shown in FIG. 10, it can be confirmed that a central portion of the flat substrate was heated to a range of 526 to 530° C. and a peripheral portion was heated to a range of 508 to 510° C. It can be confirmed that the flat substrate was heated uniformly within a relatively narrow temperature range.

In comparison, referring to FIG. 11, it can be confirmed that the existing substrate heat-treating apparatus heats the semiconductor wafer over a relatively wide temperature range. The device module of the substrate heat-treating device may supply a supply current to the VCSEL device in a constant current manner. That is, all of the device modules are supplied with the same supply current to output a laser beam. The device modules irradiate laser beams with different outputs, and the temperature range at which the semiconductor wafer is heated becomes wide. In addition, it can be confirmed that the temperature distinction between the central portion and the peripheral portion of the semiconductor wafer was not clear.

In order to help those skilled in the art to understand, the most preferred embodiments are selected from the various implementable embodiments of the present disclosure, and are set forth in the present specification. In addition, the technical spirit of the present disclosure is not necessarily restricted or limited only by these embodiments, and various changes, additions, and modification are possible without departing from the technical spirit of the present disclosure, and implementations of other equivalent embodiments are possible.

1. A substrate heat-treating apparatus, comprising:
a process chamber in which a flat substrate to be heat-treated is placed; and
a beam irradiating module comprising a plurality of vertical cavity surface emitting laser (VCSEL) devices, and configured to irradiate a laser beam to the flat substrate,
wherein the beam irradiating module is configured such that a supply current is controlled to allow outputs of the VCSEL devices to become the same.

2. The substrate heat-treating apparatus of claim 1, wherein the VCSEL devices are supplied with the supply currents which differ from each other, respectively.

3. The substrate heat-treating apparatus of claim 1, wherein a correlation between a supply current and an output is set in advance for each VCSEL device.

4. The substrate heat-treating apparatus of claim 2, wherein the correlation of the VCSEL device is set as an equation or a lookup table.

5. The substrate heat-treating apparatus of claim 3, wherein each of the VCSEL devices is supplied with a supply current for the required output depending on the correlation.

6. The substrate heat-treating apparatus of claim 1,
wherein the process chamber comprises a beam irradiating plate placed below the flat substrate, an infrared-ray transmitting plate placed above the flat substrate, a side wall in which the flat substrate is seated, an external housing in which the infrared-ray transmitting plate and an upper plate are placed above the flat substrate in the side wall, and an internal housing above which the beam irradiating plate is placed, the internal housing being placed below the flat substrate within the external housing,
wherein the beam irradiating module is placed below the beam irradiating plate within the internal housing.

7. The substrate heat-treating apparatus of claim 6, wherein the infrared-ray transmitting plate is formed from transparent quartz.

8. The substrate heat-treating apparatus of claim 6, wherein the process chamber further comprises a substrate support supporting a peripheral portion of the flat substrate, the substrate heat-treating apparatus using the VCSEL device further comprises a substrate rotating module supporting and rotating the substrate support.

9. The substrate heat-treating apparatus of claim 8, wherein the substrate rotating module comprises an inner rotating means having a ring shape in which N poles and S poles are alternately arranged in a circumferential direction and being coupled to a lower portion of the substrate support within the chamber lower space, and an outer rotating means placed outside the external housing to face the inner rotating means and configured to generate a magnetic force to rotate the inner rotating means.
